(19) United States
(12) Patent Application Publication
(10) Pub. No.: US 2018/0096820 A1
(43) Pub. Date: Apr. 5, 2018

(54) PLASMA SYSTEM

(71) Applicant: INDUSTRIAL TECHNOLOGY RESEARCH INSTITUTE, HSIN-CHU (TW)

(72) Inventors: JUI-MEI HSU, Zhubei City (TW); CHEN-DER TSAI, Hsinchu County (TW); CHIH-CHIANG WENG, Taoyuan (TW)

(21) Appl. No.: 15/378,471

(22) Filed: Dec. 14, 2016

(30) Foreign Application Priority Data
Oct. 4, 2016 (TW) 105132096

(51) Int. Cl. H01J 37/32

(52) U.S. Cl. CPC H01J 37/3277; H01J 37/3244; H01J 2237/332; H01J 2237/20221; H01J 37/32541

(57) ABSTRACT

A plasma system comprises a first electrode which connecting to a power generator and a second electrode which is grounded and disposed corresponding to the first electrode, and a spacing between the first electrode and the second electrode. A conveying device transmits a substrate of non-conductive material into and through the spacing without touching the first electrode or the second electrode. A first gas-import device is positioned closed to the first electrode and comprises a plurality of first gas-import sections. A second gas-import device is positioned closed to the second electrode. A working gas imported into the spacing between the first electrode and the second electrode is stimulated by the power generator, and plasma is generated simultaneously on both sides of the substrate.

### CROSS REFERENCE TO RELATED APPLICATION

This application claims the benefit of Taiwan application Serial No. 105132096, filed Oct. 4, 2016, the disclosure of which is incorporated by reference herein in its entirety.

### TECHNICAL FIELD

The disclosure relates in general to a plasma system, and more particularly a plasma system which is applicable to treat different sizes of substrates and which can treat simultaneously both sides of a substrate.

### BACKGROUND

It is known that various types of plasma systems are used to apply plasma treatment such as thin-film coating onto various substrates. Because the substrate is supported by a stage which is electrically connected with ground potential, continuous plasma processing of both sides of a substrate simultaneously can't be achieved.

### SUMMARY

The disclosure is directed to a plasma system which is applicable to treat different sizes of substrates and which can treat simultaneously both sides of a substrate.

According to one embodiment of the disclosure, a plasma system, comprising a first electrode, a second electrode, a conveying device, a first gas-import device, and a second gas-import device. The second electrode is oppositely disposing and having a spacing with respect to the first electrode. The conveying device transmits a substrate passing through the spacing without contacting either the first electrode or the second electrode. The first gas-import device being positioned closer to the first electrode than to the spacing, and the first gas-import device comprises a plurality of first gas-import sections which each of the first gas-import section comprises a first gas-inlet and a first gas-outlet. The second gas-import device being positioned closer to the second electrode than to the spacing. The first gas-outlet of the first gas-import device faces and is communicative to the first electrode. The substrate is made of non-conductive material, the first electrode is connected to a power generator and the second electrode is electrically connected with ground potential. A working gas imported into the spacing between the first electrode and the second electrode is stimulated by the power generator, and plasma is generated simultaneously on both sides of the substrate.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 is a schematic diagram of a plasma system according to an embodiment.

FIG. 2 is a partial cross-sectional view of the plasma system of FIG. 1 taken along the line A-A.

FIG. 3 is a cross-sectional view of the plasma system of FIG. 1 taken along the line B-B according to one embodiment.

FIG. 4 is a cross-sectional view of the plasma system of FIG. 1 taken along the line B-B according to another embodiment.

FIG. 5 is a schematic diagram of the conveying device according to one embodiment.

FIG. 6 is a schematic diagram of the conveying device according to another embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

A number of embodiments are disclosed below with accompanying drawings for elaborating the disclosure. However, the embodiments are for exemplary and explanatory descriptions only, not for limiting the scope of protection of the disclosure.

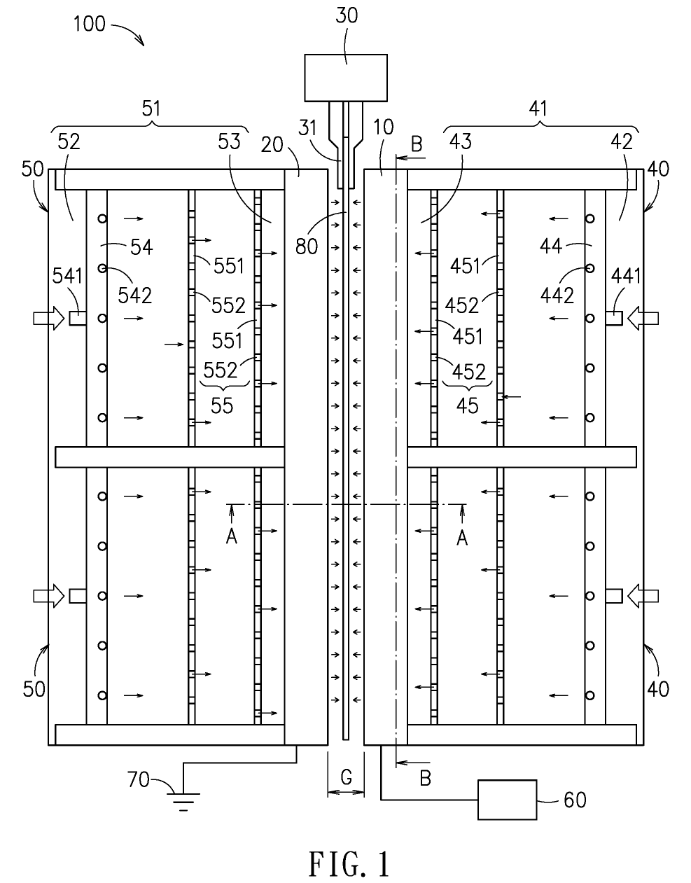

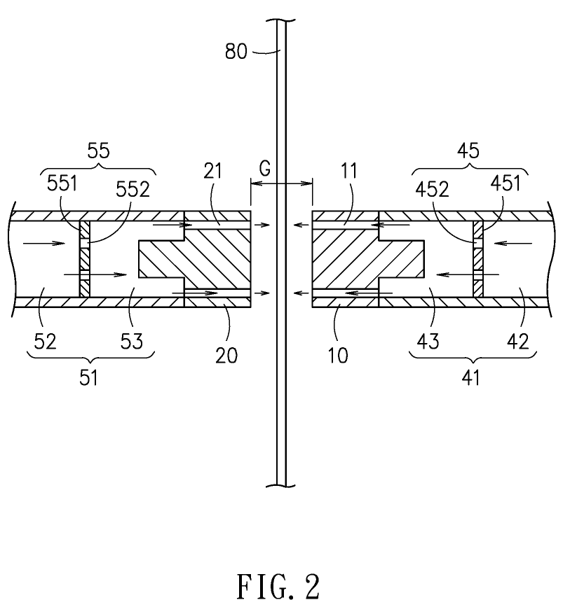

Refer to FIGS. 1 and 2. FIG. 1 and FIG. 2 are schematic diagrams of a plasma system 100 according to an embodiment. The plasma system 100 comprises a first electrode 10, a second electrode 20, a conveying device 30, a first gas-import device 40 and a second gas-import device 50.

In an embodiment, the first electrode 10 and the second electrode 20 are encapsulated in dielectric material such as dielectric ceramics. The second electrode 20 is disposed corresponding to the first electrode 10 and therefore a spacing G being formed between the first electrode 10 and the second electrode 20. The first electrode 10 is connected to a power generator 60 and the second electrode 20 is electrically connected with ground potential 70 and vice versa.

As indicated in FIG. 1, the first gas-import device 40 is positioned closer to the first electrode 10 than to the spacing G, and the first gas-import device 40 comprises a plurality of first gas-import sections 41 which each of the first gas-import section 41 comprises a first gas-inlet 42 and a first gas-outlet 43. Each of the first gas-outlet 43 of the first gas-import device 40 faces and is communicative to the first electrode 40. In FIG. 1, the first gas-import device 40 comprises two first gas-import sections 41 for example. Each of the first gas-import sections 41 comprises a first distributor 44 and a first rectifier 45 positioned between the first gas-inlet 42 and the first gas-outlet 43. The first distributor 44 is communicative to both the first gas-inlet 42 and the first rectifier 45, and the first rectifier 45 is positioned between the first distributor 44 and the first gas-outlet 43. The first gas-outlet 43 faces and is communicative to the first electrode 20. In an embodiment, the first distributor 44 comprises a hollow pipe, and the hollow pipe includes a first orifice-inlet 441 communicative to the first gas-inlet 42 and a plurality of first orifice-outlets 442 facing the first rectifier 45. The first rectifier 45 comprises at least one first perforated plate 451 including a plurality of holes 452 communicative to the first gas-outlet 43. In FIG. 1, the first rectifier 45 comprises two first perforated plates 451 for example. In an embodiment, the first gas-inlet 42 is communicative to a working gas source.

Likewise, as indicated in FIG. 1, the second gas-import device 50 is positioned closer to the second electrode 20 than to the spacing G. The second gas-import device 50 comprises at least one second gas-import section 51, and each of the second gas-import section 51 comprises a second gas-inlet 52 and a second gas-outlet 53. The second gas-outlet 53 faces and is communicative to the second electrode 20. In FIG. 1, the second gas-import device 50 comprises two second gas-import sections 51 for example. Each of the second gas-import sections 51 comprises a second distributor 54 and a second rectifier 55 positioned between the second gas-inlet 52 and the second gas-outlet 53. The second distributor 54 is communicative to both the second gas-inlet 52 and the second rectifier 55, and the second rectifier 55 is positioned between the second distributor 54 and the second gas-outlet 53. The second gas-outlet 53 faces and is communicative to the second electrode 20. In an embodiment, the second distributor 54 comprises a hollow pipe, and the hollow pipe includes a second orifice-inlet 541 communicative to the second gas-inlet 52 and a plurality of second orifice-outlets 542 facing the second rectifier 55. In an embodiment, the second rectifier 55 comprises at least one second perforated plate 551 including a plurality of holes 552 communicative to the second gas-outlet 53. In FIG. 1, the second rectifier 55 comprises two second perforated plate 551 for example. In an embodiment, the second gas-inlet 52 is communicative to a working gas source.

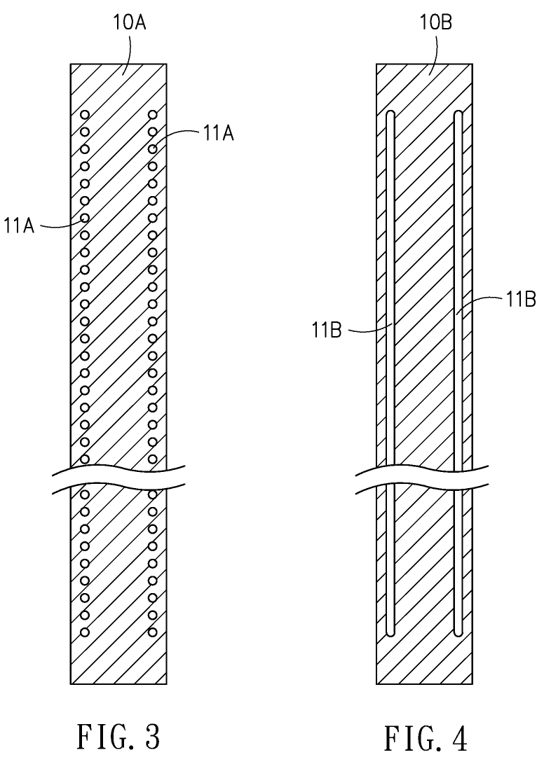

Refer to FIG. 1 and FIG. 2, the first electrode 10 comprises at least one first opening 11, which being communicative to both the spacing G and the first gas-outlet 43 of each of the first gas-import sections 41. The second electrode 20 comprises at least one second opening 21, which being communicative to both the spacing G and the second gas-outlet 53 of each of the second gas-import section 51. In an embodiment, as shown in FIG. 3, the first openings 11A being in form of a plurality of circular orifices. In another embodiment, as shown in FIG. 4, the first opening 11B being in form of two slit openings. Similarly, the second opening 21 can be in form of a plurality of circular orifices (as 11A) or two slit openings (as 11B). Besides, the first opening 11 and the second opening 21 are not limited to be in the same form.

Refer to FIG. 1, the conveying device 30 includes a gripping member 31 transmitting the substrate 80 passing through the spacing G without contacting either the first electrode 10 or the second electrode 20. The substrate 80 is made of non-conductive material.

In the present embodiment, as shown in FIG. 1, the plasma system 100 is positioned perpendicular to the ground, and the normal direction of each side of the substrate 80 is parallel to the ground. The conveying device 30 is disposed at the upper side of the plasma system 100. In another embodiment, the conveying device 30 is disposed at the lower side of the plasma system 100.

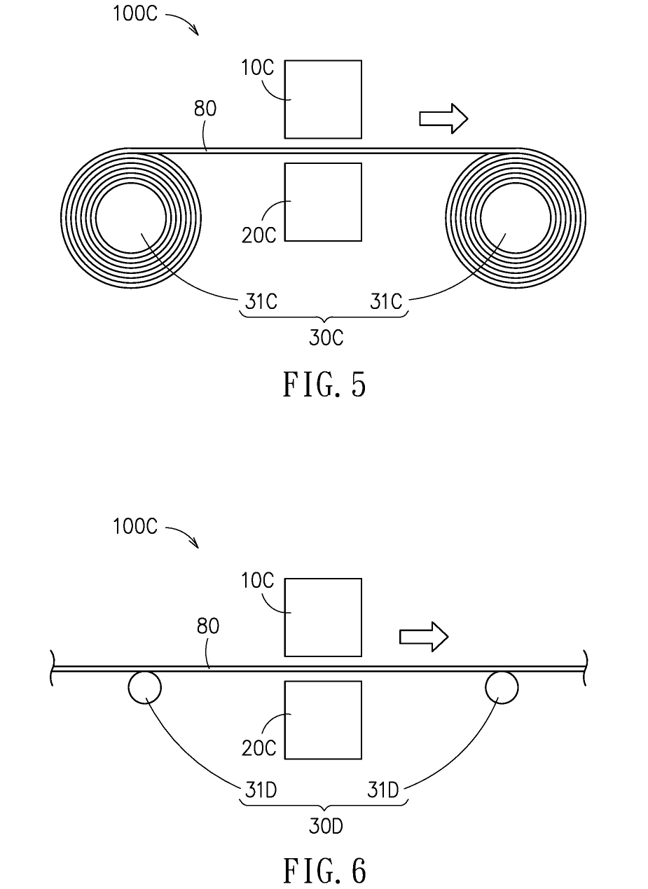

Refer to FIG. 5, the plasma system 100C is positioned parallel to the ground, and the normal direction of each side of the substrate 80 is perpendicular to the ground. In the present embodiment, the conveying device 30C includes a roll-to-roll driving member 31C for winding and transmitting the substrate 80 passing through the spacing G. In another embodiment, as shown in FIG. 6, the conveying device 30D includes at least one roller 31D for transmitting the substrate 80 being in form of a plane type passing through the spacing G. Two rollers 31D are shown in FIG. 6 for example.

FIG. 1 is schematic diagrams of a plasma system 100 according to an embodiment. The first electrode 10 is connected to a power generator 60 and the second electrode 20 is electrically connected with ground potential 70. A working gas is imported into the spacing G between the first electrode 10 and the second electrode 20 and is stimulated by the power generator 60. Then, plasma is generated simultaneously on both sides of the substrate 80. In an embodiment, the working gas is imported into some sections of the spacing G so as to generate sectional plasma simultaneously on both sides of the substrate 80. Therefore, continuous plasma processing of both sides of the substrate 80 simultaneously can be achieved.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A plasma system, comprising:
a first electrode;
a second electrode oppositely disposing and having a spacing with respect to the first electrode;
a conveying device transmitting a substrate passing through the spacing without contacting either the first electrode or the second electrode;
a first gas-import device being positioned closer to the first electrode than to the spacing, and the first gas-import device comprises a plurality of first gas-import sections which each of the first gas-import section comprises a first gas-inlet and a first gas-outlet; and
a second gas-import device being positioned closer to the second electrode than to the spacing;
wherein the first gas-outlet of the first gas-import device faces and is communicative to the first electrode; and
wherein the substrate is made of non-conductive material, the first electrode is connected to a power generator and the second electrode is electrically connected with ground potential, and a working gas imported into the spacing between the first electrode and the second electrode is stimulated by the power generator, and plasma is generated simultaneously on both sides of the substrate.

2. The plasma system as claimed in claim 1, wherein the first electrode comprises at least one first opening, which being communicative to both the spacing and the first gas-outlet of each of the first gas-import sections.

3. The plasma system as claimed in claim 1, wherein each of the gas-import sections comprises a first distributor and a first rectifier positioned between the first gas-inlet and the first gas-outlet; and
wherein the first distributor is communicative to both the first gas-inlet and the first rectifier, and the first rectifier is positioned between the first distributor and the first gas-outlet.

4. The plasma system as claimed in claim 3, wherein the first distributor comprises a hollow pipe, and the hollow pipe includes a first orifice-inlet communicative to the first gas-inlet and a plurality of first orifice-outlets facing the first rectifier.

5. The plasma system as claimed in claim 3, wherein the first rectifier comprises at least one first perforated plate including a plurality of holes communicative to the first gas-outlet.

6. The plasma system as claimed in claim 1, wherein the conveying device includes a gripping member transmitting the substrate passing through the spacing.

7. The plasma system as claimed in claim 6, wherein the plasma system is positioned perpendicular to the ground, and the normal direction of each side of the substrate is parallel to the ground.

8. The plasma system as claimed in claim 1, wherein the plasma system is positioned parallel to the ground, and the normal direction of each side of the substrate is perpendicular to the ground.

9. The plasma system as claimed in claim 8, wherein the conveying device includes a roll-to-roll driving member for winding and transmitting the substrate passing through the spacing.

10. The plasma system as claimed in claim 8, wherein the conveying device includes at least one roller for transmitting the substrate which is plane type passing through the spacing.

11. The plasma system as claimed in claim 1, wherein the first electrode is encapsulated in a dielectric material.

12. The plasma system as claimed in claim 1, wherein the second gas-import device comprises at least one second gas-import section which each of the second gas-import section comprises a second gas-inlet and a second gas-outlet, and the second gas-outlet faces and is communicative to the second electrode.

13. The plasma system as claimed in claim 12, wherein each of the second gas-import sections comprises a second distributor and a second rectifier positioned between the second gas-inlet and the second gas-outlet; and
wherein the second distributor is communicative to both the second gas-inlet and the second rectifier, and the second rectifier is positioned between the second distributor and the second gas-outlet.

14. The plasma system as claimed in claim 12, wherein the second distributor comprises a hollow pipe, and the hollow pipe includes a second orifice-inlet communicative to the second gas-inlet and a plurality of second orifice-outlets facing the second rectifier.

15. The plasma system as claimed in claim 12, wherein the second rectifier comprises at least one second perforated plate including a plurality of holes communicative to the second gas-outlet.

16. The plasma system as claimed in claim 12, wherein the second gas-inlet is communicative to a working gas source.

17. The plasma system as claimed in claim 12, wherein the second electrode comprises at least one second opening, which being communicative to both the spacing and the second gas-outlet of each of the second gas-import sections.

18. The plasma system as claimed in claim 1, wherein the second electrode is encapsulated in a dielectric material.
